(19) United States
(12) Patent Application Publication
(10) Pub. No.: US 2024/0431220 A1
(43) Pub. Date: Dec. 26, 2024

(54) ELECTRONIC DEVICE COPMPRISING A LAYER OF 2D MATERIAL

(71) Applicant: Commissariat à l'Énergie Atomique et aux Énergies Alternatives, Paris (FR)

(72) Inventors: Clotilde Ligaud, Grenoble (FR); Paul Brunet, Grenoble (FR); Emmanuel Rolland, Grenoble (FR); Pierre Trousset, Grenoble (FR)

(73) Assignee: Commissariat à l'Énergie Atomique et aux Énergies Alternatives, Paris (FR)

(21) Appl. No.: 18/750,011

(22) Filed: Jun. 21, 2024

(30) Foreign Application Priority Data
Jun. 22, 2023 (FR) 2306498

(51) Int. Cl. H10N 70/00

(52) U.S. Cl. CPC H10N 70/8822; H10N 70/028

(57) ABSTRACT

An electronic device including a stack including, in order from the top face of a substrate, a first electrode, a layer of 2D material, and a second electrode, wherein the top surface and flanks of the layer of 2D material are entirely covered by an encapsulation layer comprising at least the second electrode.

### TECHNICAL FIELD

The present description relates generally to an electronic device including a layer made of 2D material, and more particularly to an electronic device including a layer made of 2D material between two conductive layers.

### BACKGROUND ART

A 2D or two-dimensional material designates a material consisting of a single monoatomic or monomolecular sheet, or a stack of several superimposed monoatomic or monomolecular sheets, with no chemical bonding between two adjacent sheets. In other words, a 2D material is a stack of one or more crystalline planes of the same type, with no chemical bonding between two adjacent planes. In such a material, consecutive crystalline planes or sheets are bounded only by Van de Waals bonds.

Of particular interest here are 2D materials with state-change properties, i.e. the ability to switch from a relatively low-resistive state to a relatively high-resistive state, and vice versa, under the effect of polarization. The change of state of a 2D material can be ensured by two electrodes located on either side of the 2D material.

Electronic devices including such materials can take advantage of the resistive state change to implement a memory function or a switching function, for example a radio-frequency signal switching function.

### SUMMARY OF INVENTION

One embodiment overcomes some or all of the drawbacks of known electronic devices including a layer made of 2D material.

One embodiment provides an electronic device including a stack including, in order from the top face of a substrate, a first electrode, a layer of 2D material, and a second electrode, wherein the top surface and flanks of the layer of 2D material are entirely covered by an encapsulation layer comprising at least the second electrode.

According to one embodiment, the encapsulation layer has a bottom face coplanar with a bottom face of the 2D material layer.

According to one embodiment, the encapsulation layer consists only of the second electrode.

According to one embodiment, the device comprises, between the layer of 2D material and the first electrode, an insulating layer, and a conductive via passing through the insulating layer, the conductive via being in contact by a first face with said layer made of 2D material and by a second face, opposite the first face, with the first electrode.

According to one embodiment, the encapsulation layer comprises an insulating layer on, and in contact with, at least part of the flanks of the layer made of 2D material.

According to one embodiment, the layer made of 2D material is in contact by a first face with the encapsulation layer, and with the first electrode by a second face opposite the first face.

According to one embodiment, the second electrode is in contact with only part of the layer made of 2D material.

According to one embodiment, the 2D material is semiconducting.

According to one embodiment, the 2D material is based on a transition metal dichalcogenide.

According to one embodiment, the 2D material is based on molybdenum disulfide.

According to one embodiment, the layer made of 2D material is a stack of several monolayers of molybdenum disulfide and graphene.

According to one embodiment, the 2D material is based on hexagonal boron nitride.

A further embodiment provides a method of manufacturing an electronic device including forming a stack including the following consecutive steps:
forming a first electrode on the top face of a substrate;
forming a layer made of a 2D material on the top face of the first electrode; and
forming a second electrode on the top face of the layer made of 2D material, so that the top face and flanks of the layer made of 2D material are entirely covered by an encapsulation layer comprising at least the second electrode.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A, FIG. 1B, and FIG. 1C illustrate schematic and partial top view and two sectional views, respectively, of an electronic device according to a first embodiment;

FIG. 2A and FIG. 2B illustrate a schematic and partial top view and sectional view, respectively, of an electronic device according to a second embodiment;

FIG. 3A and FIG. 3B illustrate schematic and partial top view and sectional view, respectively, of an electronic device according to a third embodiment; and

FIG. 4A, FIG. 4B, and FIG. 4C illustrate schematic and partial top view and two sectional views, respectively, of an electronic device according to a fourth embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the control circuits of the memory cells or switching cells described have not been detailed, as the implementation of such control circuits is within the capabilities of those skilled in the art on the basis of the teachings of the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

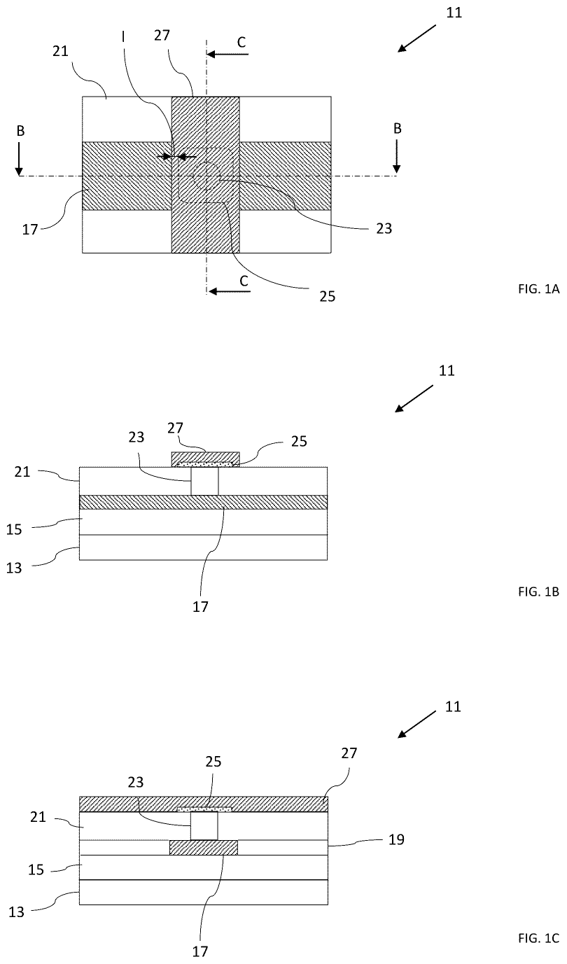

FIG. 1A, FIG. 1B, and FIG. 1C illustrate respectively schematic and partial top view and two sectional views of an electronic device 11 according to a first embodiment, FIG. 1B corresponding to the sectional view according to sectional plane BB shown in FIG. 1A, and FIG. 1C corresponding to the sectional view according to sectional plane CC shown in FIG. 1A.

The electronic device 11 corresponds, for example, to a memory cell. In practice, several memory cells can be formed side by side, for example by forming an array or matrix with rows and columns.

The electronic device 11 comprises, starting from a lower face, a substrate 13. By way of example, substrate 13 is a semiconductor substrate. For example, substrate 13 is made of a high-resistivity semiconductor material, for example with a resistivity greater than 2.3·10³ Ω·m. For example, substrate 13 is made of silicon.

The electronic device 11 comprises, for example, an insulating layer 15 covering the top face of the substrate 13. By way of example, the insulating layer 15 is in contact, by its bottom face, with the top face of the substrate 13. The insulating layer 15 covers, for example, the entire surface of the top face of the substrate 13. Insulating layer 15 is made, for example, of an oxide. For example, insulating layer 15 is made of silicon dioxide (SiO₂).

The electronic device 11 also comprises a lower electrode 17 covering at least a part of the top face of the insulating layer 15. By way of example, the lower electrode 17 is in contact, by its bottom face, with the top face of the insulating layer 15. For example, the lower electrode 17 is made of a conductive material. For example, the lower electrode 17 is made of a metallic material. By way of example, the lower electrode 17 is made of titanium, titanium nitride, copper, aluminum, tungsten, nickel and/or a mixture of one or more of these materials.

By way of example, the lower electrode 17 is common to several adjacent memory cells, for example memory cells in the same line.

The lower electrode 17 is, for example, laterally surrounded by an insulating layer 19 allowing the lower electrode 17 to be insulated from the lower electrodes of adjacent cells. For example, the insulating layer 19 is made of an oxide. For example, insulating layer 19 is made of silicon dioxide.

The electronic device 11 comprises, for example, an insulating layer 21 through which a conductive via 23 passes. By way of example, the conductive via 23 is cylindrically-shaped, with a top face and a circular bottom face. By way of example, the conductive via 23 is flush, by its top face, with the top face of layer 21. Similarly, the conductive via 23 is flush, by its bottom face, with the bottom face of layer 21, for example. The insulating layer 21 and the conductive via 23 cover, for example, the top face of the electrode 17 and the insulating layer 19. By way of example, the insulating layer 21 and the conductive via 23 are in contact, by their bottom faces, with the top face of the lower electrode 17 and the insulating layer 19. The conductive via 23 is, for example, located in line with the lower electrode 17. By way of example, conductive via 23 has a diameter smaller than the width of lower electrode 17 taken in the plane of FIG. 1C. The conductive via 23 is centered on the lower electrode 17, for example, so that it covers only a part of the surface of the top face of the lower electrode 17. By way of example, the conductive via 23 is made of a metallic material. For example, the conductive via 23 is made of platinum and/or nickel. The insulating layer 21 is, for example, made of an oxide. By way of example, insulating layer 21 is made of silicon dioxide. The conductive via 23 is, for example, between 100 nm and 1 μm high. The via 23 has, for example, a sectional area of between 0.01 μm² and 5 μm².

The electronic device 11 further comprises a layer 25 of 2D material. By way of example, the layer 25 is, when viewed from above, square- or substantially square-shaped. Layer 25 covers, for example, the top face of the conductive via 23 and of the insulating layer 21. By way of example, layer 25 is in contact by its bottom face with the top face of the conductive via 23 and of insulating layer 21. For example, layer 25 is located in line with the conductive via 23. Layer 25 is, for example, centered in line with the conductive via 23. By way of example, layer 25 covers the entire surface of the top face of conductive via 23. Layer 25 is localized and does not, for example, cover the entire top surface of insulating layer 21.

By way of example, layer 25 comprises a stack of one or more monoatomic or monomolecular sheets of 2D material. By way of example, layer 25 comprises a number of monoatomic or monomolecular sheets of less than 20, for example less than 10, for example less than 5, for example less than 3, for example less than 2, for example equal to 1. By way of example, layer 25 has a thickness in the order of a few nanometers, for example between 0.1 nm and 10 nm.

For example, layer 25 is made of a 2D semiconductor material. By way of example, layer 25 is made of a transition metal dichalcogenide or TMD material, e.g. of the formula MX₂ where “M” stands for transition metal and “X” for chalcogen. By way of example, layer 25 is made of molybdenum disulfide (MoS₂). Alternatively, layer 25 corresponds to a TMD the transition metal of which is chosen from the sixth column of the periodic table of elements. Alternatively, layer 25 is a stack of monolayers of several different 2D materials, e.g. a stack of graphene and molybdenum disulfide monolayers, or a stack of several different TMDs.

Alternatively, layer 25 is made of an insulating material, such as hexagonal boron nitride or h-BN.

By way of example, layer 25 is first formed on a growth substrate and then transferred to the top face of insulating layer 21 and conductive via 23. By way of example, the growth substrate (not shown) for layer 25 is made of silicon dioxide (SiO₂) or sapphire in the case of a molybdenum disulfide layer 25. By way of example, the growth substrate of layer 25 is made of sapphire or copper in the case of an h-BN layer 25.

The electronic device 11 further comprises an upper electrode 27 entirely covering the layer 25. The upper electrode 27 has, for example, the shape of a straight strip extending in a direction orthogonal to the direction in which the lower electrode 17 extends. By way of example, the upper electrode 27 is common to several adjacent memory cells, for example memory cells in the same column.

In the example shown, the upper electrode 27 entirely covers the entire top surface and the entire flank surface of layer 25. For example, upper electrode 27 is in contact with the entire top surface and the entire flank surface of layer 25. By way of example, upper electrode 27 further covers layer 19 in the vicinity of layer 25. By way of example, upper electrode 27 covers layer 19 on either side of layer 25 over a width l greater than 1 nm, for example greater than 10 nm, for example greater than 20 nm, for example greater than 50 nm, for example greater than 100 nm, for example greater than 200 nm, for example greater than 300 nm, for example greater than 400 nm. By way of example, the upper electrode 27 is made of a conductive material. For example, upper electrode 27 is made of a metallic material. By way of example, upper electrode 27 is made of titanium nitride. For example, the upper electrode 27 is between 50 nm and 300 nm thick, for example of the order of 100 nm.

Similar to what has been described above in relation to electrode 17, the upper electrode 27 is, for example, surrounded by an insulating layer (not shown) enabling the upper electrode 27 of the memory cells in the same column to be insulated from the upper electrode 27 of the memory cells in adjacent columns. This insulating layer is for example made of an oxide. By way of example, this insulating layer is made of silicon dioxide.

By way of example, layer 25 is located opposite the intersection of lower electrode 17 and upper electrode 27.

In the embodiment shown in FIGS. 1A to 1C, the upper electrode 27 forms an encapsulation layer entirely covering the top face and flanks of layer 25.

By way of example, the upper electrode 27 is formed by a lift-off localized deposition process. The formation of the upper electrode 27 thus comprises a step of depositing a sacrificial layer, made of resin for example, on the top face of the insulating layer 21 and of the layer 25. The sacrificial layer is made, for example, of polymethylmethacrylate or PMMA (poly(methyl methacrylate)). Once the sacrificial layer has been deposited, it is removed locally at the locations where the upper electrode 27 is to be formed. A step of depositing the material for the upper electrode 27 is then performed on the entire top face of the structure, i.e. on the top face of the sacrificial layer and in the openings made in this same layer. The final step consists of removing the sacrificial layer, leading to the removal of the layer of the material of the upper electrode 27 when it is formed on the sacrificial layer.

An advantage of the present embodiment is that the upper electrode 27 forms an encapsulation layer entirely covering the top face and flanks of layer 25. This prevents delamination of layer 25 during forming the upper electrode 27 in contact with it, and more particularly when the sacrificial layer is removed when the upper electrode 27 is formed by a lift-off localized deposition process. The inventors have indeed noticed that the stresses exerted by the metal of the upper electrode 27 cause delamination of layer 25 when the flanks of layer 25 are left free, and that the flanks of electrode 27 are therefore in contact with the top face of layer 25. The contact zone between layer 25 and the flanks of metal layer 27 is the place where delamination is initiated.

A further advantage of the present embodiment is that it protects layer 25 from external attacks, for example during subsequent method steps such as oxidation steps.

A yet further advantage of the present embodiment is that it enables the thickness of the upper electrode 27 to be increased, in order to increase its conductivity, without increasing the chance of delamination.

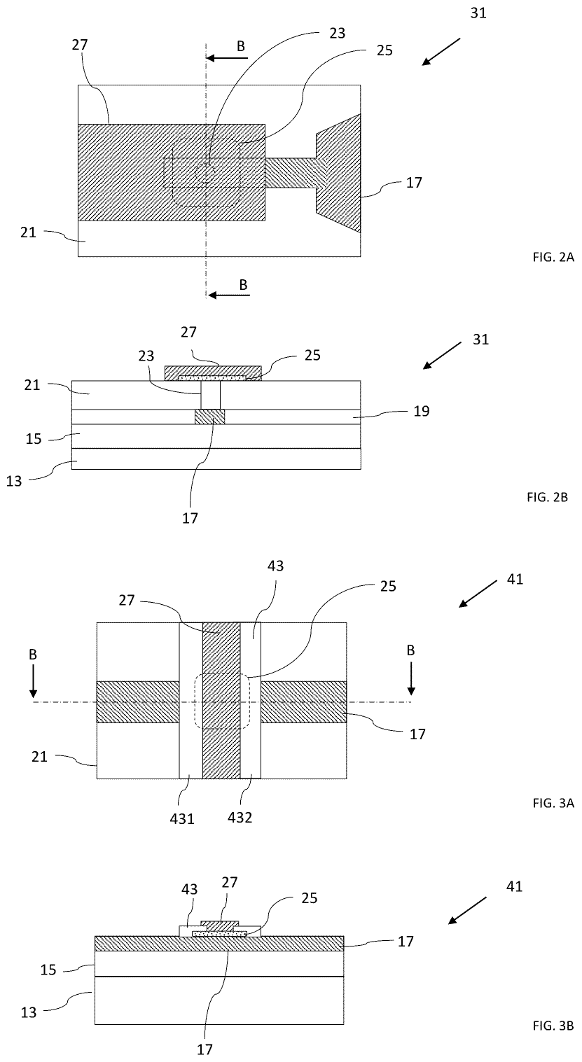

FIG. 2A and FIG. 2B illustrate, respectively, a schematic partial top view and sectional view of an electronic device 31 according to a second embodiment, with FIG. 2B corresponding to the sectional view according to sectional plane BB shown in FIG. 2A.

The electronic device 31 corresponds, for example, to a radio-frequency switch or RF switch.

The electronic device 31 is, for example, in part structurally similar to the electronic device 11 shown in FIGS. 1A to 1C, except for the geometry of the lower electrode 17 and the upper electrode 27.

By way of example, in electronic device 31, lower 17 and upper 27 electrodes extend, at least locally, in the same direction. By way of example, the electronic device 31 comprises a region in which one end of the lower electrode 17 extends in line with one end of the upper electrode 27 and in which the lower 17 and upper 27 electrodes extend along the same direction but in two opposite directions.

In FIG. 2A, for example, lower 17 and upper 27 electrodes are shown in line with each other in a central portion, with lower electrode 17 extending to the right in the orientation shown in FIG. 2A, while upper electrode 27 extends to the left. By way of example, in the region where electrodes 27 and 17 are in line, the lower electrode 17 has a width less than the width of the upper electrode 27. In this region, layer 25 has, for example, a width taken in the plane shown in FIG. 2B, higher than the width of lower electrode 17 and extends, for example, beyond in line with lower electrode 17. However, the embodiments described are not limited to this specific configuration.

In the electronic device 31, layer 25 is located between the upper electrode 27 and the lower electrode 17, and is then located opposite the end of the upper electrode 27 and opposite the end of the lower electrode 17.

In this embodiment, and similarly to what has been described in relation to the first embodiment illustrated in FIGS. 1A to 1C, the upper electrode 27 completely covers the top surface and flanks of layer 25 so as to form an encapsulation layer preventing delamination of layer 25 during forming electrode 27.

FIG. 3A and FIG. 3B show a schematic and partial top view and sectional view, respectively, of an electronic device 41 according to a third embodiment, with FIG. 3B corresponding to the sectional view according to sectional plane BB shown in FIG. 3A.

The electronic device 41 is similar to the electronic device 11 illustrated in FIGS. 1A to 1C, except that it does not comprise a conductive via 23 between the lower 17 and upper 27 electrodes, and the upper electrode 27 does not cover the entire upper surface of the layer 25.

The electronic device 41 illustrated in FIGS. 3A and 3B corresponds, for example similarly to what has been described in relation to FIGS. 1A to 1C, to a memory cell.

In the electronic device 41, for example, the lower electrode 17 is in contact, via its top face, with the bottom face of layer 25.

By way of example, upper electrode 27 is formed in line with layer 25 with a width less than the width of layer 25 taken in the plane of FIG. 3B. The upper electrode 27 is thus formed in line with layer 25 without overlapping two peripheral strips of layer 25 located on either side of the upper electrode 27.

By way of example, the electronic device 41 comprises an insulating layer 43 formed on either side of the upper electrode 27 on the peripheral parts of the layer 25 left free by the upper electrode 27. By way of example, the insulating layer 43 extends in the same direction as the upper electrode 27, i.e. orthogonally to the lower electrode 17. By way of example, insulating layer 43 comprises two portions. For example, insulating layer 43 extends over either side of upper electrode 27 from the flanks of upper electrode 27, extending over and in contact with the top face of layer 25 not covered by electrode 27. By way of example, insulating layer 43 extends to cover the flanks of layer 25 not covered by upper electrode 27. By way of example, insulating layer 45 further extends over part of the top face of the lower electrode 17 and of the layer 19.

Thus, in this example, a first portion 431 of the insulating layer 43 is in contact with the left flank of the upper electrode 27 in the orientation shown in FIG. 3A and is formed in contact with a part of the layer 25 not covered by the upper electrode 27. By way of example, the first insulating portion 431 extends beyond opposite layer 25 and extends over the top face of the device, by covering the flank of layer 25. By way of example, the portion 431 of layer 43 extends over a part of lower electrode 17 and layer 19 located in the vicinity of upper electrode 27.

Similarly, a second portion 432 of insulating layer 43 is in contact with the right-flank of upper electrode 27 in the orientation shown in FIG. 3A, for example, and is formed in contact with a part of layer 25 not covered by upper electrode 27. By way of example, the second insulating portion 433 extends beyond opposite layer 25 and extends over the top face of the device, by covering the flank of layer 25. By way of example, the portion 433 of layer 43 extends over a part of the lower electrode 17 and layer 19 located in the vicinity of the upper electrode 27.

By way of example, insulating layer 43 is made of an oxide, such as silicon oxide.

The insulating layer 43 is formed, for example, before the upper electrode 27 is formed. By way of example, insulating layer 43 is formed full plate so as to cover the entire top face of lower electrode 17 and the top face of layer 25. For example, insulating layer 43 is formed in contact with lower electrode 17 and layer 25. The insulating layer 43 is then, for example, locally removed so that it remains only opposite two peripheral strips of layer 25, in the direction orthogonal to the direction of the lower electrode 17. By way of example, at the end of this step, the insulating layer 43 is kept only over two portions extending simultaneously over layer 25 and the top face of layer 19 and lower electrode 17. In other words, insulating layer 43 is removed opposite a central strip of layer 25. The upper electrode 27 is formed, for example, after forming the insulating layer 43, by a lift-off localized deposition process. For example, the upper electrode 27 is formed so that it remains only between the two portions of layer 43. By way of example, upper electrode 27 is formed with a thickness greater than the thickness of layer 43. The upper electrode 27 extends, for example, over and in contact with part of the top face of layer 43.

In the embodiment shown in FIGS. 3A and 3B, the upper electrode 27 and the insulating layer 43 together form an encapsulation layer completely covering the top face and flanks of layer 25. This encapsulation layer, including the upper electrode 27, allows delamination of layer 25 to be prevented during formation of electrode 27. Particularly, the insulating layer 43 allows the upper electrode 27 and the lower electrode 17 to be prevented from coming into direct contact with each other.

One advantage of the present embodiment is that it allows the width of the upper electrode 27 to be reduced, thereby lowering the material cost of such a device.

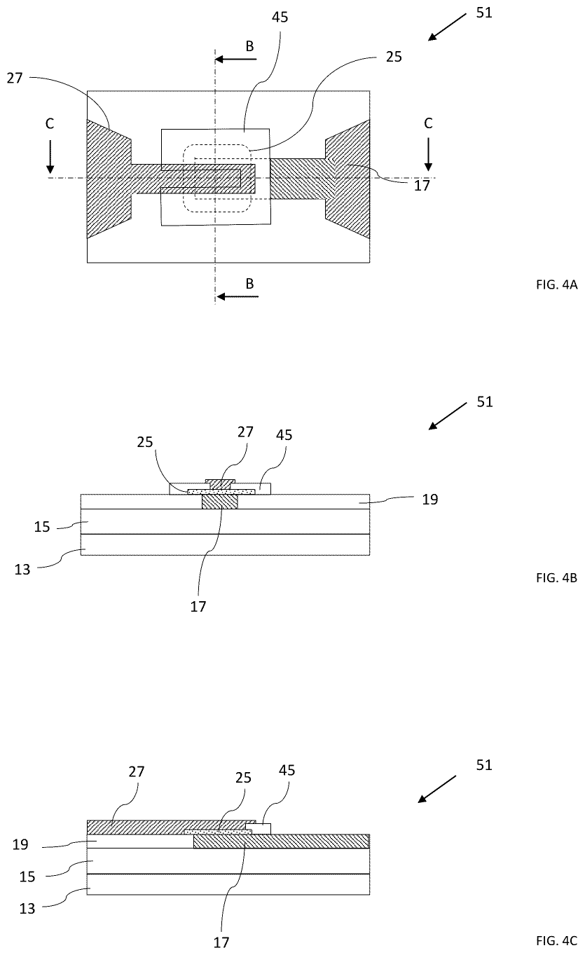

FIG. 4A, FIG. 4B and FIG. 4C show respectively schematic partial top view and two sectional views of an electronic device 51 according to a fourth embodiment, FIG. 4B corresponding to the sectional view according to sectional plane BB shown in FIG. 4A, and FIG. 4C corresponding to the sectional view according to sectional plane CC shown in FIG. 4A.

The electronic device 51 corresponds, for example, to a radio-frequency switch or RF switch.

The electronic device 51 is, for example, in part structurally similar to the electronic device 41 illustrated in FIGS. 3A to 3C. The electronic device 51 differs from the device 41 in particular in the geometry of the lower electrode 17 and of the upper electrode 27.

By way of example, in the electronic device 51, and similar to what has been described in relation to FIGS. 2A and 2B, the lower 17 and upper 27 electrodes extend, at least locally, in the same direction. The electronic device 51 comprises, for example, a region in which one end of the lower electrode 17 extends in line with an end of the upper electrode 27, and in which the lower 17 and upper 27 electrodes extend along the same direction but in two opposite directions.

In the electronic device 51, the layer 25 is located between the upper electrode 27 and the lower electrode 17, and more particularly between the respective ends of the upper 27 and lower 17 electrodes.

In the embodiment shown in FIGS. 4A to 4C, layer 25 has, for example, a width in the plane shown in FIG. 4B which is greater than the width of lower electrode 17. Layer 25 extends in this plane, for example, beyond the part in line with the lower electrode 17, extending over part of the upper face of layer 19 in the vicinity of lower electrode 17.

By way of example, upper electrode 27 is in contact with layer 25. By way of example, the upper electrode 27 covers the top face of layer 25, leaving three peripheral portions of layer 25 free and uncovered by the upper electrode 27.

Similar to what has been described in relation to FIGS. 3A and 3B, the upper electrode 27 is surrounded, opposite layer 25, by an insulating layer 45. The insulating layer 45 is, for example, similar in composition to the insulating layer 43 illustrated in FIGS. 3A and 3B. In the embodiment shown in FIGS. 4A to 4C, the insulating layer 45 is in the shape of a “U” surrounding the end of the upper electrode 27. By way of example, the layer 45 does not extend along the upper electrode 27 as described in relation to FIGS. 3A and 3B.

Insulating layer 45 extends, for example, from the three flanks of upper electrode 27 opposite layer 25, extending opposite layer 25 to cover the parts of layer 25 not covered by upper electrode 27. Layer 45 further covers the flanks of layer 25 not covered by upper electrode 27, and extends over part of the top face of layer 19 in the vicinity of layer 25. By way of example, in electronic device 51, upper electrode 27 and lower electrode 17 are not in direct contact with each other.

Here again, the insulating layer 45 and the upper electrode 27 form an encapsulation layer completely covering the top face and flanks of layer 25, allowing a delamination of layer 25 to be prevented when the upper electrode 27 is formed.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. An electronic device including a stack including, in order from the top face of a substrate, a first electrode, a layer of 2D material, and a second electrode,
wherein the top surface and flanks of the layer of 2D material are entirely covered by an encapsulation layer comprising at least the second electrode.

2. The device according to claim 1, wherein the encapsulation layer has a bottom face coplanar with a bottom face of the 2D material layer.

3. The device according to claim 1, wherein the encapsulation layer consists only of the second electrode.

4. The device according to claim 3, comprising, between the layer of 2D material and the first electrode, an insulating layer, and a conductive via passing through the insulating layer, the conductive via being in contact by a first face with said layer made of 2D material and by a second face, opposite the first face, with the first electrode.

5. The electronic device according to claim 1, wherein the encapsulation layer comprises an insulating layer on, and in contact with, at least part of the flanks of the layer made of the 2D material.

6. The device according to claim 5, wherein the layer made of 2D material is in contact by a first face with the encapsulation layer, and with the first electrode by a second face opposite the first face.

7. The device according to claim 5, wherein the second electrode is in contact with only part of the layer made of 2D material.

8. The device according to claim 1, wherein the 2D material is semiconducting.

9. The device according to claim 1, wherein the 2D material is based on a transition metal dichalcogenide.

10. The device according to claim 9, wherein the 2D material is based on molybdenum disulfide.

11. The device according to claim 1, wherein the layer made of 2D material is a stack of several monolayers of molybdenum disulfide and graphene.

12. The device according to claim 1, wherein the 2D material is based on hexagonal boron nitride.

13. A method of manufacturing an electronic device including forming a stack including the following consecutive steps:
forming a first electrode on the top face of a substrate;
forming a layer made of a 2D material on the top face of the first electrode; and
forming a second electrode on the top face of the layer made of 2D material, so that the top face and flanks of the layer made of 2D material are entirely covered by an encapsulation layer comprising at least the second electrode.
